(19) United States
(12) Patent Application Publication
(10) Pub. No.: US 2026/0239941 A1
(43) Pub. Date: Aug. 13, 2026

(54) NITROGEN GETTERING FROM A METAL BY USE OF A SELECTIVELY DEPOSITED METAL

(71) Applicant: Applied Materials, Inc., Santa Clara, CA (US)

(72) Inventors: Thomas EMPANTE, Santa Clara, CA (US); Jeffrey W. ANTHIS, San Jose, CA (US); Daniel Wei Ming BEH, Sunnyvale, CA (US); Michael HAVERTY, Santa Clara, CA (US); Joung Joo LEE, San Jose, CA (US); Avgerinos V. GELATOS, Scotts Valley, CA (US)

(21) Appl. No.: 19/281,318

(22) Filed: Jul. 25, 2025

Related U.S. Application Data
(60) Provisional application No. 63/758,266, filed on Feb. 13, 2025.

(51) Int. Cl. H01L 21/768; C23C 16/16; C23C 16/18; C23C 16/52

(52) U.S. Cl. CPC H10W 20/032; C23C 16/16; C23C 16/18; C23C 16/52; H10W 20/038

(57) ABSTRACT

Embodiments of the present disclosure generally relate to methods and apparatus for forming thin films. More particularly, embodiments of the present disclosure generally relate to methods and apparatus of selectively depositing a gettering metal atop an exposed metal surface. Embodiments of the present disclosure include a method of forming a capping layer. The method of forming a capping layer includes selectively depositing a cobalt capping layer on an exposed metal surface formed on a substrate using a vapor deposition process and selectively depositing a gettering metal layer atop an exposed surface of the cobalt capping layer.

### CROSS-REFERENCE TO RELATED APPLICATIONS

This application claims benefit of United States provisional patent application Ser. No. 63/758,266, filed Feb. 13, 2025, which is herein incorporated by reference.

### BACKGROUND

### Field

Embodiments of the present disclosure generally relate to methods and apparatus for forming thin films. Specifically, embodiments of the present disclosure generally relate to methods and apparatus of selectively depositing a gettering metal atop an exposed metal surface.

### Description of the Related Art

In the formation of metal interconnects, for example copper (Cu) interconnects, depositing a cobalt (Co) capping layer between the copper interconnect and the subsequently formed dielectric layer improves the adhesion between the metal and the dielectric as well as the reliability of the interface between the metal and the dielectric. The current state of the art uses a cobalt deposition process that employs NH3 plasma to enhance the selectivity and growth rate of cobalt onto the copper interconnects. However, this NH3 plasma process is a source of nitrogen (N) which can poison and contaminate the molybdenum (Mo) metal layer causing an undesirable increase in resistivity.

Therefore, there is a need for an improved metal capping layer that solves the problems described above.

### SUMMARY

Embodiments of the present disclosure generally relate to methods and apparatus for forming thin films. More particularly, embodiments of the present disclosure generally relate to methods and apparatus of selectively depositing a gettering metal atop an exposed metal surface.

Embodiments of the present disclosure include a method of forming a capping layer. The method of forming a capping layer includes selectively depositing a cobalt capping layer on an exposed metal surface formed on a substrate using a vapor deposition process and selectively depositing a gettering metal layer atop an exposed surface of the cobalt capping layer.

Embodiments of the present disclosure further include a computer readable medium, having instructions stored thereon which, when executed, cause a processing chamber to perform a method of selectively depositing a gettering metal layer atop an exposed surface of a cobalt capping layer in copper interconnects. The method includes exposing a substrate, comprising a dielectric layer having an exposed dielectric surface and a metal layer having an exposed metal surface, to a reducing gas at a temperature of about 200 degrees Celsius to about 800 degrees Celsius, or to a plasma formed from a reducing gas to remove contaminants from a surface of the exposed metal surface and dielectric surface. The method further includes selectively depositing a cobalt capping layer atop the exposed metal surface using a vapor deposition process and selectively depositing a gettering metal layer atop the exposed surface of the cobalt capping layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic plan view of an exemplary embodiment of a processing system in accordance with one or more embodiments described herein.

FIG. 2 is a process flow diagram for a method of selectively depositing a gettering metal atop an exposed metal surface in accordance with one or more embodiments described herein.

FIGS. 3A, 3B, 3C, 3D, 3E, 3F, and 3G are sectional views of various stages of a process for selectively depositing a gettering metal atop an exposed metal surface in accordance with one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure provide methods and apparatus for the formation of improved metal capping layers that include a capping metal layer and a gettering metal layer. In some embodiments, the gettering metal layer is selectively deposited on an exposed surface of the capping metal layer (e.g., a cobalt capping layer) that is formed over a metal interconnect (e.g., a copper interconnect). The gettering metal layer (e.g., aluminum, vanadium, chrome, etc.) is selected so that it preferentially getters one or more elements (e.g., nitrogen) found within the capping layer thus improving the contact resistance, device speed, and reliability of the formed electronic device. In one example, embodiments of the present disclosure also generally include methods of selectively depositing a gettering metal, such as aluminum, atop the exposed metal surface of the cobalt capping layer formed over a copper interconnect layer.

### Example Multi-chamber Processing System

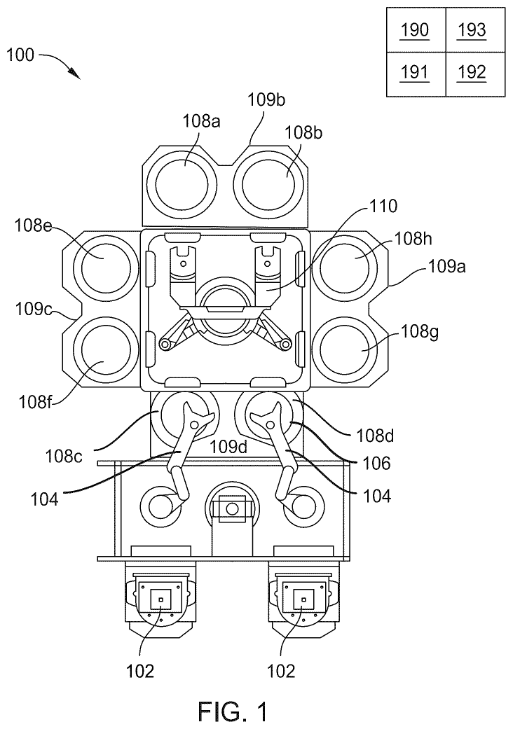

FIG. 1 illustrates a top plan view of one exemplary embodiment of a processing system 100 according to embodiments disclosed herein. One processing system that can be used to advantage is The Producer® platform available from Applied Materials, Inc. located in Santa Clara, CA.

As shown in FIG. 1, a pair of front opening unified pods 102 supply substrates that are received by robotic arms 104 and placed into one of the substrate processing chambers 108a-h, positioned in tandem sections 109a-d. A second robotic arm 110 transports the substrates from the holding area between the processing chambers 108a-h and back. Each substrate processing chamber 108a-h, can be outfitted to perform a number of substrate processing operations including the selective deposition of a cobalt capping layer and a gettering metal described herein in addition to plasma-enhanced chemical vapor deposition, atomic layer deposition, physical vapor deposition, etch, pre-clean, degas, orientation, and other substrate processes including, annealing, ashing, etc. Substrates can be processed in and transferred between the various chambers maintained at a low pressure, or a vacuum environment, without breaking the low pressure or vacuum environment between process steps performed on the substrates in the substrate processing system 100.

The processing chambers 108a-h may include one or more system components for depositing, annealing, curing and/or etching a dielectric or other film on the substrate. In one configuration, two pairs of the processing chambers, e.g., 108c-d, may be used to form a barrier layer within a feature of a device structure, to fill the feature with a conductor material, and to passivate exposed dielectric surfaces. A second pair of processing chambers, e.g., 108a-b, may be used for the selective deposition of a cobalt capping layer by a vapor deposition process. And a third pair of processing chambers, e.g., 108e-f or 108g-h may be used for the selective deposition of a gettering metal atop the exposed surface of a cobalt capping layer.

As shown, a controller 190 is in communication with the processing system 100 and is used to control processes and methods, such as the operations of the methods described herein. The controller 190 is configured to receive data or input as sensor readings from sensor(s). The sensor devices can include, for example: sensor devices that monitor pressure in the processing chambers, e.g., 108e-f.

The controller 190 includes a central processing unit (CPU) 193 (e.g., a processor), a memory 191 containing instructions, and support circuits 192 for the CPU 193. The controller 190 controls various items directly, or via other computers and/or controllers. In one embodiment which can be combined with other embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like.

The controller 190 is configured to conduct any of the operations described herein. The instructions stored on the memory, when executed by the CPU 193, cause one or more of the operations described herein to be conducted in relation to the processing system 100. The controller 190 and the processing system 100 are at least part of a system for processing substrates.

The various operations described herein can be conducted automatically using the controller 190, or can be conducted automatically or manually with certain operations conducted by a user.

### Processing Sequence Example

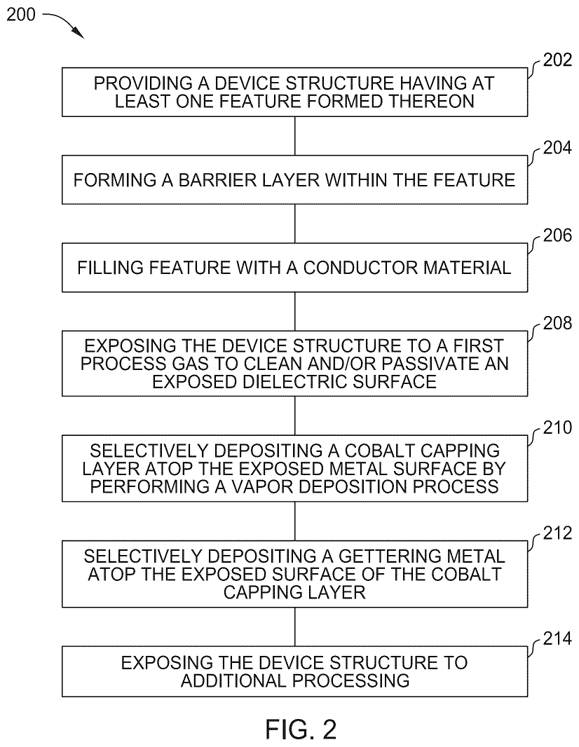

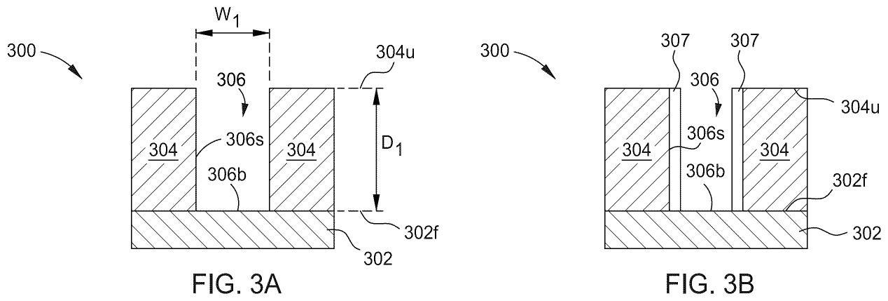

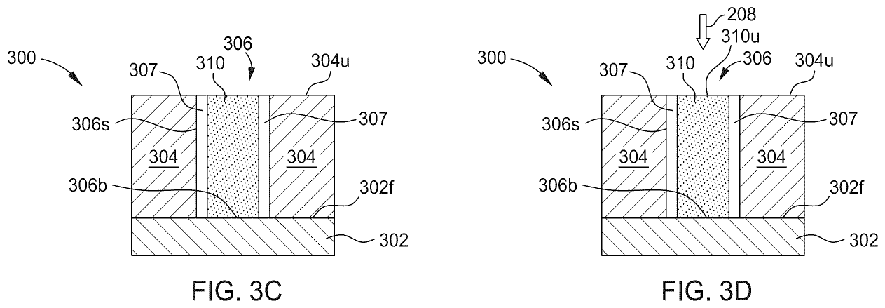

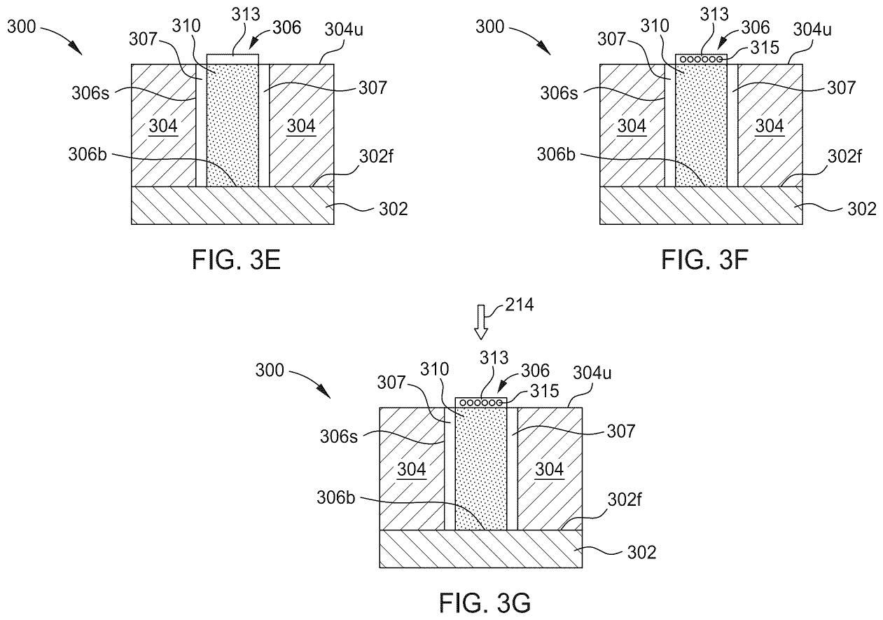

FIG. 2 illustrates a process flow diagram for the formation of a metal capping layer that includes a capping layer metal and a gettering metal layer. FIGS. 3A-3G illustrate views of various stages of one embodiment of selectively depositing a cobalt capping layer and a gettering metal layer atop an exposed metal surface.

Although the method 200 is described in relation to FIGS. 3A-3G, it will be appreciated that the method 200 is not limited to the structures disclosed in FIGS. 3A-3G, but may be used to advantage with other structures. It should be understood that FIGS. 3A-3G illustrate only partial schematic views of a semiconductor device structure 300, and the semiconductor device structure 300 may contain any number of transistor, capacitor, or other useful sections and additional materials having aspects as illustrated in the figures. It should also be noted that although the method 200 illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations and includes a surface to be cleaned. The substrate may be a silicon based material, or any suitable insulating materials or conductive materials as needed. The substrate may include a material such as crystalline silicon (e.g., Si<100>or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

Referring to FIG. 2, at operation 202, a semiconductor device structure 300 having a feature formed thereon is provided. FIG. 3A illustrates a cross-sectional view of the semiconductor device structure 300 during an intermediate stage of manufacturing corresponding to operation 202. The semiconductor device structure 300 includes a device substrate 302 having one or more layers formed thereon, for example, a dielectric layer 304. The device substrate 302 may be or include a bulk semiconductor substrate, a semiconductor-on-insulator (SOI) substrate, or the like, which may be doped (e.g., with a p-type dopant or an n-type dopant) or undoped. In some embodiments, the semiconductor material of the device substrate 302 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 302 may include additional materials, for example, silicide layers, metal silicide layers, metal layers, dielectric layers, etch stop layers, interlayer dielectrics, or a combination thereof.

The device substrate 302 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 302 to generate the structural and functional requirements of the design for the resulting semiconductor device structure 300.

The device substrate has a frontside 302f (also referred to as a front surface). The dielectric layer 304 is formed over the frontside 302f of the device substrate 302. The dielectric layer 304 may include multiple layers. The dielectric layer 304 includes an upper surface 304u or field region. In some embodiments, the dielectric layer 304 includes a dielectric material, such as a low k dielectric (SiCOH), silicon oxide, silicon dioxide (SiO2), silicon nitride (Si3N4), silicon carbide (SiC), silicon oxynitride (SiON), aluminum oxide (Al2O3), aluminum nitride (AlN), a combination thereof, or multi-layers thereof. In some embodiments, the dielectric layer 304 consists essentially of silicon oxide. It is noted that the foregoing descriptors, for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The dielectric layer 304 is patterned to form one or more feature(s) 306. The feature 306 may be a high aspect ratio (HAR) feature. In some embodiments, the feature 306 can be selected from a trench, a via, a hole, or a combination thereof. In particular embodiments, the feature is a trench. In other particular embodiments, the feature 306 is a via. In some embodiments, the feature 306 extends from the upper surface 304u of the dielectric layer 304 toward the frontside 302f of the device substrate 302. The feature 306 includes sidewall surface(s) 306s and a bottom surface 306b extending between the sidewall surface(s) 306s. In some embodiments, the sidewall surface(s) 306s is tapered. The sidewall surface(s) 306s may be defined by the dielectric layer 304 and the bottom surface may be defined by the device substrate 302. The sidewall surface(s) 306s may be defined by a dielectric material and the bottom surface 306b may be defined by a dielectric material or other materials, for example, a silicide layer, a metal silicide layer, a semiconductor layer, an etch stop layer (ESL), or a previously deposited metal layer.

In some embodiments, the sidewall surface(s) 306s is defined by the dielectric layer 304 and the bottom surface 306b may also be defined by the dielectric layer 304, for example, where the feature 306 is a trench structure. In other embodiments, the sidewall surface(s) 306s is defined by the dielectric layer 304 and the bottom surface 306b is defined by a conductive material, for example, where the feature 306 is a via or bottom contact structure. The conductive material may be formed of copper (Cu), cobalt (Co), molybdenum (Mo), tungsten (W), or ruthenium (Ru). The feature 306 has a first depth “D1” from the upper surface 304u to the bottom surface 306b and a width “W1” between the two sidewall surface(s) 306s. In some embodiments, the depth D1 is in a range of 2 nm to 200 nm. In some embodiments, the width W1 is in a range of 10 nm to 100 nm. In some embodiments, the feature 306 has an aspect ratio (D/W) in a range of 1 to 20.

In some embodiments, the semiconductor device structure 300 may have a native oxide layer (not shown) or other contaminants formed on the sidewall surface(s) 306s, the bottom surface 306b, or both the sidewall surface(s) 306s and the bottom surface 306b of the feature 306. The semiconductor device structure 300 may be exposed to atmosphere prior to or during processing, which may lead to the formation of the native oxide layer (not shown) on the surfaces of the feature and substrate. For example, if a vacuum break occurs prior to or during the method 200, the vacuum break can lead to the formation of native oxides. In addition, other processes performed prior to or during the method 200 may lead to the formation of additional contaminants or debris on the sidewall surface(s) 306s and the bottom surface 306b of the feature 306.

In some embodiments, the semiconductor device structure 300 is exposed to a pretreatment process. The pretreatment process can include one or more native oxide or contamination removal processes for removing the contamination and/or native oxide layer (if present). The pretreatment process of operation 204 of can include one or more dry clean processes. Any suitable dry clean process may be performed. The dry clean process may include a plasma etch process, such as a two-part dry chemical clean process using NF3 and NH3, and H2 and O2 plasma etch process, an H2 plasma etch process, or a combination thereof.

In some embodiments, which can be combined with other embodiments, the feature 306 is exposed to a dry clean process and/or a degas process prior to formation of a barrier layer over the exposed inner surfaces of the feature 306 and on the exposed surfaces of the dielectric layer 304 during operation 204. The dry clean process may be used to remove oxides from the surface of the feature 306. The clean process may be performed in a processing chamber positioned on a cluster tool, for example, processing chambers 108c-d of the processing system 100.

In one or more embodiments, which can be combined with other embodiments, the substrate and the feature may be exposed to a fluorine-containing precursor and a hydrogen-containing precursor in a two-part dry chemical clean process. In one or more embodiments which can be combined with other embodiments, the fluorine-containing precursor may include nitrogen trifluoride (NF3), hydrogen fluoride (HF), diatomic fluorine (F2), monatomic fluorine (F), fluorine-substituted hydrocarbons, combinations thereof, or the like. In one or more embodiments, which can be combined with other embodiments, the hydrogen-containing precursors may include atomic hydrogen (H), diatomic hydrogen (H2), ammonia (NH3), hydrocarbons, incompletely halogen-substituted hydrocarbons, combinations thereof, or the like.

In one or more embodiments, which can be combined with other embodiments, the first part of the two-part dry clean process includes using a remote plasma source to generate an etchant species, for example, ammonium fluoride (NHF4), from the fluorine-containing precursor, for example, nitrogen trifluoride (NF3), and the hydrogen-containing precursor, for example, ammonia (NH3). By using a remote plasma source, damage to the substrate may be minimized. The etchant species may then be introduced into a pre-clean chamber, for example, the processing chambers 108c-d depicted in FIG. 1, and condensed into a solid by-product on the surface of the substrate through a reaction with the native oxides present on the surface. The second part of the two-part dry clean process may then include an in-situ anneal to decompose the by-product using convection and radiation heating. The by-product then sublimates and may be removed from the surface of the feature via a flow of gas and pumped out of the pre-clean chamber.

In one or more embodiments, which can be combined with other embodiments, the pre-treatment process is a plasma treatment process. The plasma treatment process can be an inductively coupled plasma (ICP) process or a capacitively coupled plasma (CCP) process. The plasma can be formed ex-situ in a remote plasma source (RPS). The plasma can be a direct plasma formed in-situ, for example, generated within a processing region. In one or more embodiments, which can be combined with other embodiments, the plasma treatment process includes exposing the device 300 to a plasma formed from a process gas including a hydrogen-containing gas. In one or more embodiments, which can be combined with other embodiments, the plasma treatment process includes exposing the substrate to a plasma formed from a process gas including both a hydrogen-containing gas and an oxygen-containing gas. In one example, the plasma treatment process includes exposing the feature 322 to an ICP formed from a process gas including a hydrogen-containing gas and an oxygen-containing gas. The process gas may further include an inert gas, for example, argon (Ar), helium (He), krypton (Kr), or a combination thereof. In one or more embodiments, which can be combined with other embodiments, the plasma treatment process includes exposing the feature to a plasma formed form a process gas including one or more of H2, O2, Ar, or a combination thereof. In one or more embodiments, which can be combined with other embodiments, the plasma treatment process can include exposing the feature to a hydrogen and oxygen plasma treatment. The hydrogen and oxygen plasma treatment can include a saturation conformal treatment, which includes a longer soak time and/or high reactant treatment, to provide for good subsequent metal-fill of the feature.

In one or more embodiments, which can be combined with other embodiments, the plasma treatment process is performed at temperatures of 400° C. or less. In one or more embodiments, which can be combined with other embodiments, the plasma treatment process includes supplying a processing gas including H2 greater than or equal to 90% of the total flow of hydrogen and oxygen.

Referring to FIG. 2, at operation 204 a barrier layer is formed over the feature 306. FIG. 3B illustrates a cross-sectional view of the semiconductor device 300 during intermediate stages of manufacturing corresponding to the operation 204. In one or more embodiments, the barrier layer 307 may serve as an electrical and/or physical barrier between the dielectric layer 304 and a metal-containing layer to be subsequently deposited in the opening during block 206. In another embodiment, which may be combined with one or more embodiments, the barrier layer 307 may function as a better surface for attachment during the subsequent deposition of a metal-containing layer than a native surface of the substrate. The barrier layer 307 may be or include a metal layer, a metal, for example, tantalum, cobalt, titanium, tungsten, copper, ruthenium, the like, or a combination thereof. The barrier layer 307 may be a conformal layer. The barrier layer 307 may be a nonconformal layer. The barrier layer 307 may be or include a metal, for example, tantalum, cobalt, titanium, tungsten, copper, ruthenium, the like, or a combination thereof. Although a single layer is depicted the barrier layer 307 may include one or more additional conformal/nonconformal layers, for example, one or more of barrier, adhesion, and/or grain modification layers. The one or more additional conformal/nonconformal layers can include or be a nitride, for example, silicon nitride, carbon nitride, aluminum nitride, tantalum nitride, titanium nitride, tungsten nitride, the like, or a combination thereof, or a carbide, for example, tungsten carbide, aluminum carbide, the like, or a combination thereof. In some embodiments, the barrier layer may contain a tantalum/tantalum nitride bilayer or titanium/titanium nitride bilayer. The barrier layer 307 may be formed by any suitable deposition process such as atomic layer deposition (ALD), chemical vapor deposition (CVD), physical vapor deposition (PVD), or a hybrid ALD/CVD process. The barrier layer 307 may be formed by a selective vapor deposition process, for example, a selective ALD, a selective CVD, or a selective hybrid ALD/CVD process. Barrier layer 307 can be molybdenum-free. In one or more embodiments, which can be combined with other embodiments, the barrier layer 307 has an initial thickness in a range from about 1 Å to about 100 Å, or in a range from about 10 Å to about 50 Å, or in a range from about 20 Å to about 50 Å, or in a range from about 10 Å to about 20 Å. The barrier layer 307 may be or include a tungsten layer deposited via a PVD process.

In one or more embodiments, which can be combined with other embodiments, the barrier layer 307 is formed over or directly on at least a portion of the at least one feature 306. In some embodiments, as is shown in FIG. 3B, the barrier layer may be selectively formed over or directly only on the sidewall surface(s) 306s of the feature 306 and the barrier layer 307 either does not form or minimally forms on the bottom surface 306b of the feature 306 and on the exposed the upper surface of 304u or field region of the dielectric layer 304. In some embodiments, the barrier layer 307 may be selectively formed over or directly on the sidewall surface(s) 306s of the feature 306 and over or on the upper surface 304u or field region of the dielectric layer 304. That is, the barrier layer 307 either does not form or minimally forms on the bottom surface 306b of the feature 306. In some embodiments, the barrier layer 307 may be or include a tungsten layer. The tungsten layer may be formed directly on the sidewall surface(s) 306s of the feature 306 and over or on the upper surface 304u or field region of the dielectric layer 304. The barrier layer 307 may be or include a tungsten layer having an initial thickness in a range from about 1 Å to about 100 Å, or in a range from about 20 Å to about 50 Å. In some embodiments, the barrier layer 307 may be discontinuous along for example, the sidewall surface(s) 306s and/or the bottom surface 306b. The deposition of the barrier layer 307 may be performed in a processing chamber positioned on a cluster tool, for example, processing chambers 108c-d of the processing system 100 shown in FIG. 1.

Referring to FIG. 2, at operation 206, the feature 306 is filled with a conductive material by performing a deposition process. FIG. 3C illustrates a cross-sectional view of the device 300 during intermediate stages of manufacturing corresponding to operation 206. In one or more embodiments, the conductive material is a metal material such as copper, molybdenum, tungsten, titanium nitride, cobalt or the like. The conductive material is a metal that has a desirable work function.

The deposition process can include filling the feature 306 with metal layer 310 by any suitable metal deposition process known in the art, for example ALD process, a PVD process, a CVD process, or the like. The metal fill process in block 206 may include a CVD process using a tungsten-containing precursor, such as WF6, a cobalt containing precursor, or molybdenum-containing precursors, such as MoCl5. In one or more embodiments, the metal fill process is performed in a processing chamber, such as the processing chambers 108c-d shown in FIG. 1.

In one or more embodiments, a polishing process, such as a chemical mechanical polishing (CMP) process may subsequently be performed to remove excess metal layer 310 and excess barrier layer 307 material from the field region 304u of the dielectric layer 304. In some embodiments the CMP process may result in the formation of contaminants on the exposed metal surface 310u of the metal layer 310 and the field region 304u of the dielectric layer 304. For example, where the metal layer is copper, contaminants usually contain copper oxides formed during or after the polishing process. The exposed metal surfaces 310u of the metal layer 310 may be oxidized by peroxides, water, or other reagents in the polishing solution or by oxygen within the ambient air. Contaminants may also include moisture, polishing solution remnants including surfactants and other additives, or particles of polished away materials.

Contaminants may be removed by exposing the device structure 300 to a cleaning process where the contaminants are exposed to a reducing gas. In some embodiments, the substrate may be exposed to the reducing gas prior to, or concurrent with exposing the substrate to the pretreatment process during block 202. In some embodiments, the reducing gas includes hydrogen (e.g., H2 or atomic-H), ammonia (NH3), a hydrogen and ammonia mixture (H2/NH3), atomic-N, hydrazine (N2H4), alcohols (e.g., methanol, ethanol, or propanol), derivatives thereof, plasmas thereof, or combinations thereof. In some embodiments, the substrate may be exposed to the reducing gas in a thermal process or in a plasma process. For example, in a thermal process, the substrate may be exposed to the reducing gas and heated to temperature of about 200 degrees Celsius to about 800 degrees Celsius for about 2 minutes to about 20 minutes. For example, in a plasma process, the substrate 200 can be exposed to a reducing gas and heated to a temperature of about 100 degrees Celsius to about 800 degrees Celsius. The substrate may be exposed to a plasma, generated at a power of about 200 Watts to about 1000 Watts, for about 2 seconds to about 180 seconds. In some embodiments, the substrate is also exposed to the reducing gas and simultaneously to a UV light source in order to activate the reducing gas. The UV light source may be of any wavelength sufficient to activate the reducing gas. In some embodiments, the UV light may have a wavelength of about 100 nm to about 400 nm, or more specifically about 180 nm to about 200 nm.

Referring to FIG. 2, at operation 208, the device substrate 208 is exposed to a first process gas to clean and/or passivate the exposed regions of the semiconductor device structure 300. FIG. 3D illustrates a cross-sectional view of the device 300 during an intermediate stage of manufacturing corresponding to operation 208. The first process gas passivates the field region 304u of the dielectric layer 304 in preparation for the deposition of a metal capping layer, e.g., a cobalt capping layer. In one or more embodiments, exposing the field region 304u of the dielectric layer 304 to the first process gas improves (i.e., reduces) the dielectric constant of the dielectric layer by about 1 percent to about 10 percent. In some embodiments, the first process gas may comprise alcohols such as ethanol, propanol, butanol, or the like. In some embodiments, the first process gas may comprise a vinyl silane containing compound.

In one or more embodiments, the device 300 is exposed to the first process gas at a temperature of about 25 degrees Celsius to about 400 degrees Celsius. For example, in some embodiments, as discussed below, where the method 200 is performed in a single apparatus, such as that of FIG. 1, the substrate is exposed to the first process gas at a temperature of about 250 degrees Celsius to about 350 degrees Celsius. In some embodiments, where block 202 is performed in one apparatus and block 204, as described below, is performed in a second apparatus, the device 300 is exposed to the first process gas at a temperature of about 25 degrees Celsius to about 400 degrees Celsius. In some embodiments, the device 300 is exposed to the first process gas for about 10 seconds to about 300 seconds, for example from about 10 seconds to about 60 seconds. In some embodiments, the flow rate of the first process gas to the processing chamber is about 10 sccm to about 1000 sccm, for example about 50 sccm to about 400 sccm. In some embodiments, the substrate is exposed to the first process gas at a chamber pressure of about 1 Torr to about 100 Torr. In some embodiments, the first process gas further comprises hydrogen gas (H2) and an inert gas, such as argon, helium, krypton or the like.

Referring to FIG. 2, at operation 210, a cobalt capping layer is selectively deposited atop the exposed metal surface using a vapor deposition process. FIG. 3E illustrates a cross-sectional view of the device 300 during an intermediate stage of manufacturing corresponding to operation 210.

In one or more embodiments, the cobalt capping layer 313 is deposited by exposing the surface of the device 300 to a metal-containing precursor gas, such as a cobalt precursor gas, in a processing chamber, such as the processing chambers 108a-b shown in FIG. 1, via a suitable thermal deposition process, e.g., a thermal chemical vapor deposition (CVP) process or thermal atomic layer deposition (ADL) process. In some embodiments, the device 300 is exposed to the cobalt precursor gas at a temperature suitable for thermal deposition, for example at a temperature of about 200 degrees Celsius to about 250 degrees Celsius. In some embodiments, the cobalt precursor gas may be provided to the processing chamber along with a carrier gas, for example an inert gas, such as argon, helium, nitrogen or the like. In some embodiments, suitable reactant gases that may be provided to the processing chamber that are useful to forming cobalt material include hydrogen, ammonia, nitrogen, argon and combinations thereof.

The metal-containing precursor gas is preferably suitable for thermal deposition processes and may include cobalt carbonyl complexes, cobalt dienyl complexes, cobalt nitrosyl complexes, derivatives thereof, complexes thereof, plasma thereof, or combinations thereof. In some embodiments, cobalt carbonyl compounds or complexes may be utilized as the metal-containing precursors. In some embodiments, cobalt amido complexes may be utilized as the metal-containing precursor. In some embodiments, the metal-containing precursor gas is a cobalt amidinate complex.

In some embodiments, the ratio of the rate of cobalt deposition on the exposed metal surface to the rate of cobalt deposition on the exposed dielectric surface is about 200:1 to about 3000:1. In some embodiments, the thickness of the cobalt layer is about 10 angstroms to about 40 angstroms. In some embodiments, an inert gas, for example, argon, helium, krypton, or the like, is supplied to the processing chamber along with the cobalt precursor gas.

Referring to FIG. 2, at operation 212, a gettering metal layer 315 is selectively deposited atop the exposed surface of the cobalt capping layer 313. FIG. 3F illustrates a cross-sectional view of the device 300 during an intermediate stage of manufacturing corresponding to the operation 210.

The selective gettering metal deposition process can include the deposition of a gettering metal layer 315 (e.g., aluminum) via a chemical vapor deposition (CVD) process in processing chambers, such as the processing chambers 108e-f shown in FIG. 1. In some embodiments, during the chemical vapor deposition process, the device is exposed to a gettering metal precursor gas at a temperature suitable for thermal deposition, for example at a temperature of about 200 degrees Celsius.

In one or more embodiments, the CVD process includes using metal gettering precursors for the selective gettering metal deposition process. The metal gettering precursors that can be used to advantage have nitrogen gettering potential and display strong metal-nitride bond energies (e.g., aluminum). In some examples, the gettering metal layer 315 precursors include low-valent metal precursors comprising hafnium (Hf), zirconium (Zr), aluminum (Al), vanadium (V), gallium (Ga), titanium (Ti), tantalum (Ta), niobium (Nb), boron (B), chrome (Cr), silicon (Si), beryllium (Be), or the like.

In one or more embodiments, the selective gettering metal deposition process includes selectively depositing aluminum, i.e., an aluminum metal layer 315 (also referred above as the gettering metal layer 315), atop the exposed surface of the cobalt capping layer 313. In one example, the chemical vapor deposition of the aluminum metal layer 315 is maintained for a period of about 5 seconds to about 20 seconds at a chamber pressure of about of about 1 Torr to about 1.5 Torr while maintaining a substrate temperature of about 200 degrees Celsius. In one or more embodiments, the aluminum metal layer 315 may have a thickness of about 5 angstroms to about 15 angstroms.

Referring to FIG. 2, optionally at operation 214, the semiconductor device 300 is exposed to additional processing. FIG. 3G illustrates a cross-sectional view of the device 300 during an intermediate stage of manufacturing corresponding to the operation 214. In some embodiments, an annealing process may be performed during operation 214 to diffuse the nitrogen away (i.e., up) from the molybdenum metal layer (i.e., from the metal layer 310) towards the nitrogen gettering metal 315 deposited during block 212, thus reducing the nitrogen contamination and decreasing resistivity of the device structure 300.

Beneficially, embodiments of the disclosure provide a method and apparatus for the formation of an improved metal capping layer that includes a capping layer metal and a gettering metal layer. In some embodiments, the gettering metal is selectively deposited on an exposed surface of the capping metal layer (e.g., cobalt capping layer) that is disposed over a copper interconnect. The gettering metal (e.g., aluminum, vanadium, chrome, etc.) is selected so that it preferentially getters one or more elements (e.g., nitrogen) found within the capping layer, thus improving the contact resistance, device speed and reliability of the formed electronic device. In one example, embodiments of the present disclosure also generally include methods of selectively depositing a gettering metal, such as aluminum, atop the exposed metal surface of the cobalt capping layer formed over a copper interconnect layer.

While the foregoing is directed to embodiments of the present disclosure, other and further embodiments of the disclosure may be devised without departing from the basic scope thereof, and the scope thereof is determined by the claims that follow.

What is claimed is:

1. A method of forming a capping layer, comprising:
selectively depositing a cobalt capping layer on an exposed metal surface formed on a substrate using a vapor deposition process; and
selectively depositing a gettering metal layer atop an exposed surface of the cobalt capping layer.

2. The method of claim 1, further comprising:
exposing the substrate to a first process gas to passivate an exposed dielectric surface of the substrate prior to selectively depositing the cobalt capping layer, wherein the substrate comprises a dielectric layer having the exposed dielectric surface and a metal layer having the exposed metal surface.

3. The method of claim 2, wherein the first process gas reduces a dielectric constant of the dielectric layer by about 1 to about 10 percent.

4. The method of claim 2, wherein the first process gas comprises alcohols such as ethanol, propanol, or butanol.

5. The method of claim 2, wherein the first process gas comprises a vinyl silane containing compound, hydrogen, and an inert gas such as argon, or krypton.

6. The method of claim 1, wherein the vapor deposition process includes maintaining a first temperature of the substrate and providing a first carrier gas, and a first metal-containing precursor.

7. The method of claim 6, wherein the first temperature of the substrate is about 200 degrees Celsius to about 250 degrees Celsius.

8. The method of claim 6, wherein the first carrier gas comprises an inert gas such as argon, helium, or nitrogen.

9. The method of claim 6, wherein the first metal-containing precursor comprises cobalt carbonyl complexes, cobalt dienyl complexes, cobalt nitrosyl complexes, derivatives thereof, complexes thereof, plasma thereof, or combinations thereof.

10. The method of claim 1, wherein the gettering metal layer is selectively deposited using a chemical vapor deposition process.

11. The method of claim 10, wherein the chemical vapor deposition process includes maintaining a second temperature of the substrate and providing a second carrier gas, and a second metal-containing precursor.

12. The method of claim 11, wherein the second temperature of the substrate is about 200 degrees Celsius.

13. The method of claim 11, wherein the second metal-containing precursor comprises a gettering metal precursor gas, the gettering metal precursor gas comprising low-valent metal precursors.

14. The method of claim 11, wherein the second metal-containing precursor comprises at least one of Hafnium (Hf), Zirconium (Zr), Aluminum (Al), Vanadium (V), Gallium (Ga), Titanium (Ti), Tantalum (Ta), Niobium (Nb), Boron (B), Chrome (Cr), Silicon (Si), and Beryllium (Be).

15. The method of claim 1, wherein the gettering metal layer has a thickness of about 5 angstroms to about 15 angstroms.

16. The method of claim 10, wherein the chemical vapor deposition process includes maintaining a chamber pressure of about 1Torr to about 1.5 Torr.

17. A computer readable medium, having instructions stored thereon which, when executed, cause a processing chamber to perform a method of selectively depositing a gettering metal layer atop an exposed surface of a cobalt capping layer in copper interconnects, the method comprising:
exposing a substrate, comprising a dielectric layer having an exposed dielectric surface and a metal layer having an exposed metal surface, to a reducing gas at a temperature of about 200 degrees Celsius to about 800 degrees Celsius, or to a plasma formed from a reducing gas to remove contaminants from a surface of the exposed metal surface and the exposed dielectric surface;
selectively depositing the cobalt capping layer atop the exposed metal surface
using a vapor deposition process; and
selectively depositing the gettering metal layer atop the exposed surface of the cobalt capping layer.

18. The method of claim 17, wherein the gettering metal layer is selectively deposited using a chemical vapor deposition process.

19. The method of claim 18, wherein the gettering metal layer is deposited at a substrate temperature of about 200 degrees Celsius.

20. The method of claim 17, wherein the gettering metal layer comprises at least one of Hafnium (Hf), Zirconium (Zr), Aluminum (Al), Vanadium (V), Gallium (Ga), Titanium (Ti), Tantalum (Ta), Niobium (Nb), Boron (B), Chrome (Cr), Silicon (Si), and Beryllium (Be).
